(19) United States
(12) Patent Application Publication
(10) Pub. No.: US 2017/0243954 A1
(43) Pub. Date: Aug. 24, 2017

(54) METHOD OF FABRICATING FINFET DEVICE

(71) Applicant: UNITED MICROELECTRONICS CORP., Hsin-Chu City (TW)

(72) Inventors: Jhen-Cyuan Li, New Taipei City (TW); Sheng-Hsu Liu, Changhua County (TW); Shui-Yen Lu, Tainan City (TW)

(21) Appl. No.: 15/047,636

(22) Filed: Feb. 19, 2016

(51) Int. Cl. H01L 29/66; H01L 21/265; H01L 29/08

(52) U.S. Cl. CPC H01L 29/66795; H01L 29/0847; H01L 21/26513

(57) ABSTRACT

A method of forming a FinFET device includes following steps. First of all, a fin shaped structure is formed on a substrate. Then, a portion of the fin shaped structure is removed to form a first trench in the fin shaped structure. Next, a cover film is formed to partially cover surfaces of the first trench and to expose a portion of the fin shaped structure. Afterward, the exposed portion of the fin shaped structure is further removed to form a second trench under the first trench. Finally, a barrier layer is formed on surfaces of the second trench, thereby improving the current leakage issues.

### BACKGROUND OF THE INVENTION

### 1. Field of the Invention

The present invention relates to a method of forming a semiconductor device, and more particularly, a method of forming a fin field-effect transistor (FinFET) device.

### 2. Description of the Prior Art

For the sake of increasing the carrier mobility of a semiconductor structure, a compressive stress or tensile stress can be optionally applied to a gate channel. In conventional arts, a selective epitaxial growth (SEG) process is used to form required stress. For example, after the formation of a gate on a silicon substrate, a silicon-germanium (SiGe) epitaxial structure is formed in the predetermined location, in which the lattice arrangement of silicon (Si) and germanium (Ge) are similar to each other. Since the lattice constant of the SiGe layer is larger than a lattice constant of Si, accordingly, the band structure of Si may be changed, and the compressive stress is then formed and applied to the channel region of a P-type metal-oxide-semiconductor (PMOS) transistor, thereby increasing the carrier mobility in the channel region, as well as increasing the efficiency of the PMOS transistor. On the other hand, a silicon carbide (SiC) epitaxial structure can be optionally formed in the silicon substrate of an N-type metal-oxide-semiconductor (NMOS) transistor, to apply the tensile stress to the channel region of the NMOS transistor.

While the foregoing method can improve the carrier mobility in the channel region, said method also has led to the difficulty of the overall fabrication process and the process control, especially under the trend of miniaturization of semiconductor device dimensions. Hence, there is a need of proving a novel fabrication method of a semiconductor structure, to obtain more reliable semiconductor devices.

### SUMMARY OF THE INVENTION

It is one of the primary objectives of the present invention to provide a method of fabricating a FinFET device, which can improve current leakage through forming a barrier layer at the interface between the substrate and the source/drain regions, thereby boosting the performance of the entire FinFET device.

To achieve the purpose described above, the present invention provides a method of fabricating a FinFET device including following steps. First of all, a fin shaped structure is formed on a substrate. Then, a portion of the fin shaped structure is removed to form a first trench in the fin shaped structure. Next, a cover film is formed to partially cover surfaces of the first trench and to expose a portion of the fin shaped structure. Afterward, the exposed portion of the fin shaped structure is further removed to form a second trench under the first trench. Finally, a barrier layer is formed on surfaces of the second trench.

According to the above, the method of forming the FinFET device in the present invention includes forming a cover film after a trench is formed to expose a bottom surface of the trench, forming another trench through the exposed bottom surface and forming an epitaxial layer on surfaces of the another trench. It is worth noting that the epitaxial layer preferably includes a complementary conductive type relative to the gate structure, such that the epitaxial layer may function like an anti-type barrier layer, thereby preventing from current leakage through an interface between the substrate (silicon) and the source/drain regions (epitaxial layer).

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 7 are schematic diagrams illustrating a fabricating method of a FinFET device according to a first preferred embodiment of the present invention, in which:

FIG. 1 shows a cross-sectional view of a FinFET device at the beginning of a fabricating process of the present invention;

FIG. 2 shows a cross-sectional view of a FinFET device after forming a first trench;

FIG. 3 shows a cross-sectional view of a FinFET device after forming a material layer;

FIG. 4 shows a cross-sectional view of a FinFET device after forming a cover film;

FIG. 5 shows a cross-sectional view of a FinFET device after forming a second trench;

FIG. 6 shows a cross-sectional view of a FinFET device after forming an epitaxial layer in the second trench;

FIG. 7 shows a cross-sectional view of a FinFET device after forming an epitaxial structure filled in the first trench.

FIG. 8 is a schematic diagram illustrating a fabricating method of a FinFET device according to a second preferred embodiment of the present invention.

FIG. 9 is a schematic diagram illustrating a fabricating method of a FinFET device according to a third preferred embodiment of the present invention.

### DETAILED DESCRIPTION

To provide a better understanding of the present invention, preferred embodiments will be described in detail. The preferred embodiments of the present invention are illustrated in the accompanying drawings with numbered elements.

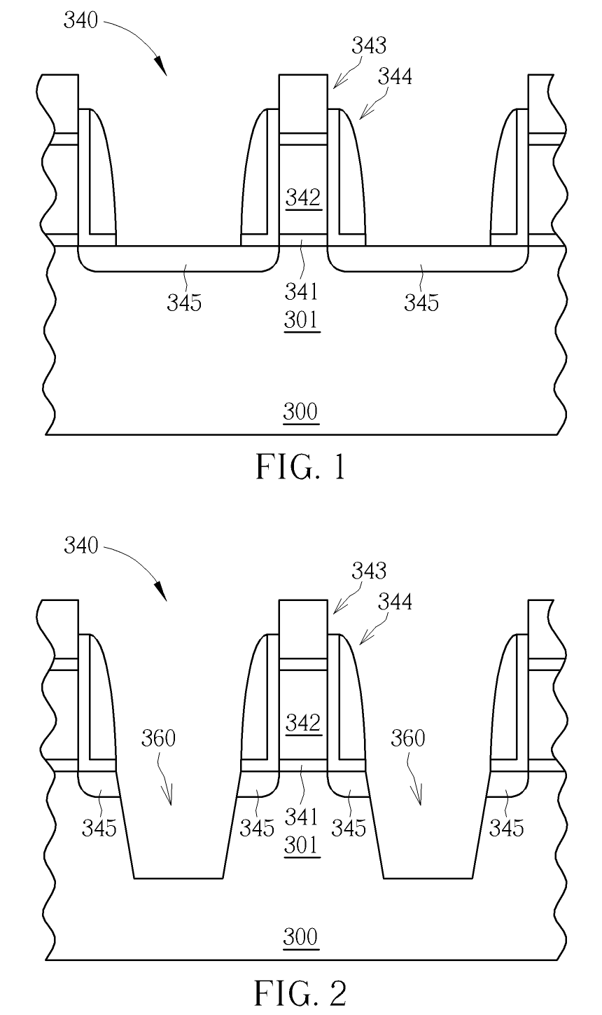

Please refer to FIG. 1 to FIG. 7, and which illustrate a fabricating method of a FinFET device in accordance with the first preferred embodiment of the present invention. First of all, a substrate 300 is provided in which the substrate 300 for example includes a silicon containing substrate, an epitaxial silicon substrate or a silicon-on-insulator (SOI) substrate, and a plurality of gate structures 340 is formed on the substrate 300 as shown in FIG. 1.

In the present embodiment, at least one fin shaped structure 301 and an insulating layer (not shown in the drawings) are formed in the substrate 300, and the gate structure 340 is then formed across the fin shaped structure 301. In one embodiment of the present invention, the method of fabricating the fin shaped structure 301 may include forming a patterned mask (not shown in the drawings) on the substrate 300, transferring patterns of the patterned mask to the substrate 300 through an etching process, removing the patterned mask to form a plurality of trenches (not shown in the drawings) in the substrate 300, and finally forming the insulating layer to fill in the trenches. Accordingly, a portion of the substrate 300 may protrude from the insulating layer to form the fin shaped structure 301 and the insulating layer may form shallow trench isolations (STIs, not shown in the drawings). However, in another embodiment of the present invention, the fin shaped structure may also be omitted while a planar transistor (not shown in the drawings) is required to be formed and the gate structure may be formed directly on a planar substrate (not shown in the drawings). Also, in another embodiment, the shallow trench isolation (namely the insulating layer) may also be omitted while a SOI substrate (not shown in the drawings) is provided.

Specifically, the gate structure 340 for example includes a gate insulating layer 341, a gate electrode 342, a capping layer 343, a spacer 344 and a light doped drain (LDD) region 345. The gate insulating layer 341 may include silicon dioxide (SiO₂), silicon nitride (SiN) or a high dielectric constant (high-k) material; the gate electrode 342 may include polysilicon like undoped polysilicon, doped polysilicon, amorphous silicon or a composite material of the combination thereof; the capping layer 343 may include a multilayer structure shown in FIG. 1 for example including SiO₂, silicon carbide (SiC), SiN, oxynitride (SiON) or a combination thereof, but is not limited thereto. In one embodiment of the present invention, a capping layer including a monolayer structure may also be formed in accordance with the practical requirements. The spacer 344 may also include a monolayer structure or a multilayer structure optionally for example including high temperature oxide (HTO), SiN, SiO₂, SiON, silicon carbonitride (SiCN) or SiN formed by hexachlorodisilane (Si₂Cl₆) (HCD-SiN). In one embodiment of the present invention, the formation of the gate structure 340 may include the following steps. Firstly, a gate insulating material layer (not shown in the drawings), a gate material layer (not shown in the drawings) and a capping material layers (not shown in the drawings) are stacked on the substrate 300, and those stacked layers are patterned to form a gate stack structure (not shown in the drawings). Subsequently, the LDD region 345 is formed in the fin shaped structure 301 (substrate 300) at two sides of the gate stack structure, and the spacer 344 is formed on sidewalls of the gate stack structure, thereby forming the gate structure 340. It is noted that the formation of the gate structure in the present invention is not limited to the above-mentioned steps and may further include other fabrication methods or processes which are well known by one skilled in the arts. For example, a metal gate structure (not shown in the drawings) at least including a work function layer and a metal gate may also be formed on the substrate 300 in another embodiment of the present invention.

Next, at least one etching process is performed to form a trench 360 at two sides of the gate structure 340 in the fin shaped structure 301 (substrate 300). In the present embodiment, only one etching process such as a dry etching process or a wet etching process is performed to form the trench 360 so that the trench 360 may have a cross-section being increased from bottom to top, for example being a trapezoid shape as shown in FIG. 2. In another embodiment of the present invention, the formation of the trench 360 may include sequentially performing an anisotropic etching process like a dry etching process and an isotropic etching process like a wet etching, thereby forming a trench (not shown in the drawings) in a hexagon shaped (also known as sigma τ) or octagon shaped.

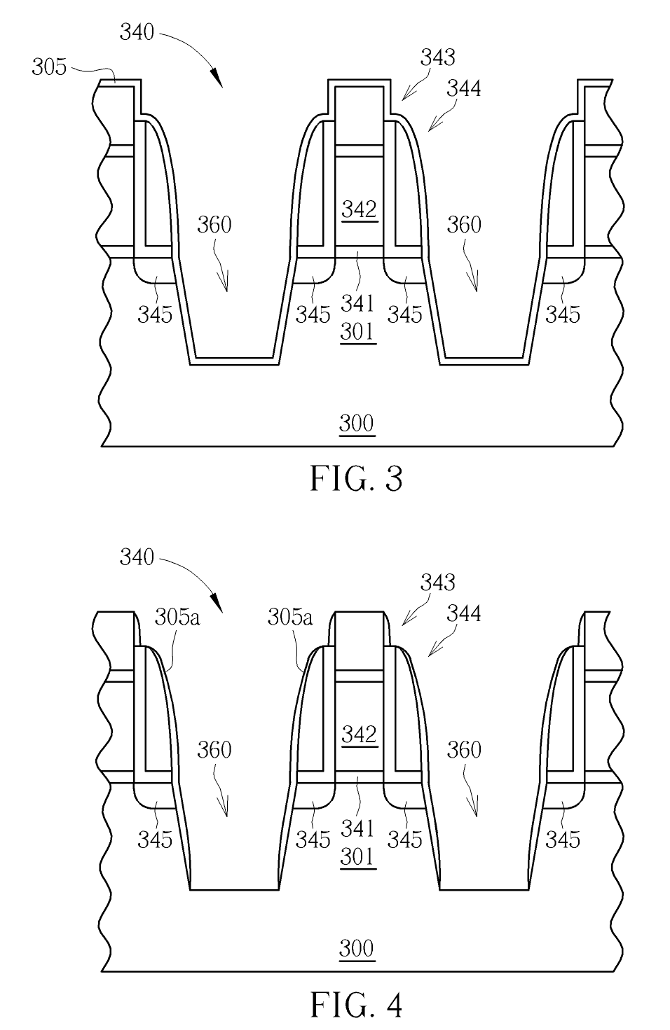

Then, a cover film 305a is formed on the substrate 300 to cover the gate structure 340 and the majority of the substrate 300 and to expose a portion of the fin shaped structure 301 as shown in FIG. 4. The cover film 305a preferably includes a proper mask material such as oxide and the formation thereof may include firstly forming a material layer 305 as shown in FIG. 3 to cover the substrate 300, the gate structure 340 and the entire surfaces of the trench 360 and performing an etching back process to remove a portion of the material layer 305 covered on a bottom surface of the trench 360, thereby forming the cover film 305a exposing the bottom surface of the trench 360. Also, through such etching back process, a portion of the gate structure 340 maybe simultaneously exposed from the cover film 305a, for example a top portion of the capping layer 343 and a top portion of the spacer 344 as shown in FIG. 4.

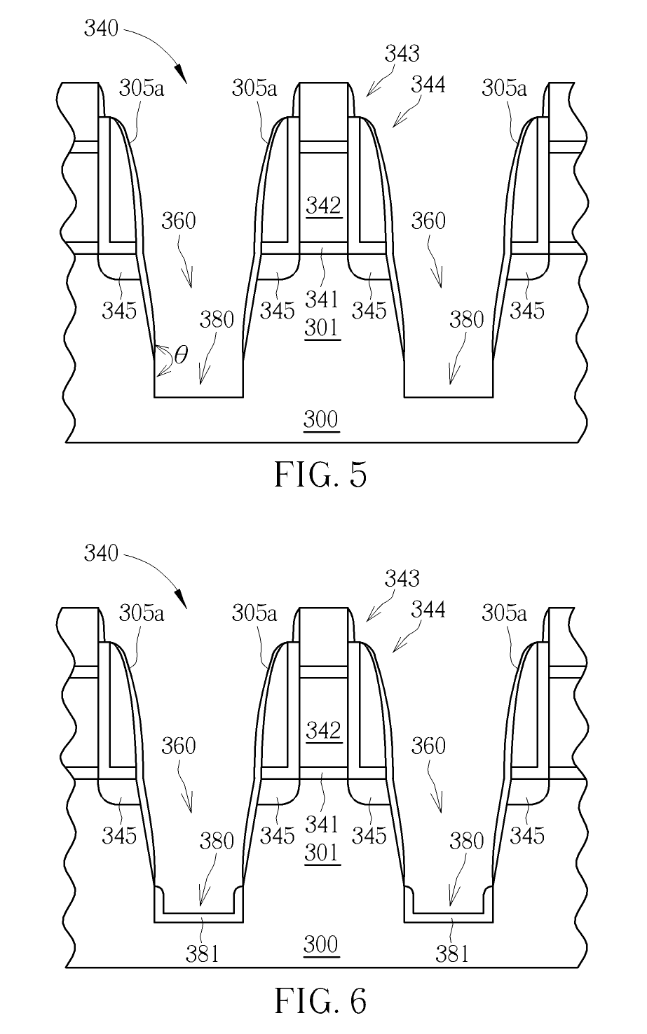

Following these, another etching process is performed to form another trench 380 under the trench 360. Specifically, the etching process is namely performed by using the cover film 305a as a mask to further etch the substrate 300 exposed therefrom. In other words, the exposed portion (namely, the exposed bottom surface) of the trench 360 is etched so that the trench 380 maybe formed within the extension area of the trench 360 in a projecting direction, as shown in FIG. 5. In this manner, the trench 380 is formed downwardly from the trench 360 and there is an angle θ formed according between the sidewalls of the trench 380 and the trench 360 as shown in FIG. 5.

Afterward, a selective epitaxial growth (SEG) process is performed to form an epitaxial layer 381 in the trench 380. In the present embodiment, the epitaxial layer 381 is formed on surfaces of the trench 380 as shown in FIG. 6, but is not limited thereto. In one embodiment, the epitaxial layer 381 may include adjustable material according to the conductive type of the transistor required to be formed. For example, if the gate structure 340 is required to form a PMOS transistor in the subsequent processes, the epitaxial layer 381 may include N-type conductive materials such as N-doped silicon. On the other hand, if the gate structure 340 is required to form a NMOS transistor in the subsequent processes, the epitaxial layer 381 may include P-type conductive materials such as P-doped silicon. Also, in another embodiment, the epitaxial layer 381 may be formed for example through an in situ doping process to dope heterogeneous atoms such as germanium or carbon atoms in the epitaxial layer 381, but is not limited thereto. In another embodiment, the proper dopant may also be doped in gradual arrangement.

Finally, another SEG process is performed to form an epitaxial structure 361 to fill in the trenches 380, 360, for providing required compressive stress or tensile stress to the channel of the gate structure 340, in which the material of the epitaxial structure 361 may have the same conductive type according to that of the transistor required to be formed. For example, if the gate structure 340 is required to form a PMOS transistor in the subsequent processes, the epitaxial structure 361 may include SiGe, SiGeB, or SiGeSn; alternately, if the gate structure 340 is required to form a NMOS transistor in the subsequent processes, the epitaxial structure 361 may include SiC, SiCP, or SiP. After that, an ion implantation process is performed to form source/drain regions (not shown in the drawings) at least in a portion of the epitaxial structure 361. In the present embodiment, the source/drain regions may also be in-situ formed while the SEG process is carried out. For example, if the gate structure 340 is required to form a PMOS transistor, the epitaxial structure 361 may be in-situ doped with a P type dopant such as boron (B) to form a P+ epitaxial structure thereby; or if the gate structure 340 is required to form a NMOS transistor, the epitaxial structure 361 may be in-situ doped with an N type dopant to form a N+ epitaxial structure. Thus, the following ion implantation process for forming the source/drain regions of PMOS/NMOS may be omitted. However, the formation of the epitaxial structure 361 is not limited to the aforementioned steps and may further include other forming process. For example, in another embodiment, the epitaxial structure 361 may be formed to extend over the top surface of the substrate 300, or in a multilayer structure, or to further dope heterogeneous atoms such as germanium or carbon atoms in a gradual arrangement, preferably with the surface of the epitaxial structure 361 having a relative lighter concentration or no germanium at all.

Through this manner, the forming method according to the first embodiment of the present invention is complete, in which a cover film is formed after a trench is formed to expose a bottom surface of the trench, and then another trench is formed through the exposed bottom surface and an epitaxial layer is formed on surface of the another trench. It is worth noting that the epitaxial layer preferably includes complementary conductive type relative to the gate structure, such that the epitaxial layer may function like an anti-type barrier layer, thereby preventing from current leakage through an interface between the substrate (the silicon) and the source/drain region (the epitaxial structure).

However, the anti-type barrier layer in the present invention is not limited to be formed through the aforementioned steps and the following description will detail other different embodiments or variant embodiments thereof. To simplify the description, the following description will detail the dissimilarities among the different embodiments and the identical features will not be redundantly described. In order to compare the differences between the embodiments easily, the identical components in each of the following embodiments are marked with identical symbols.

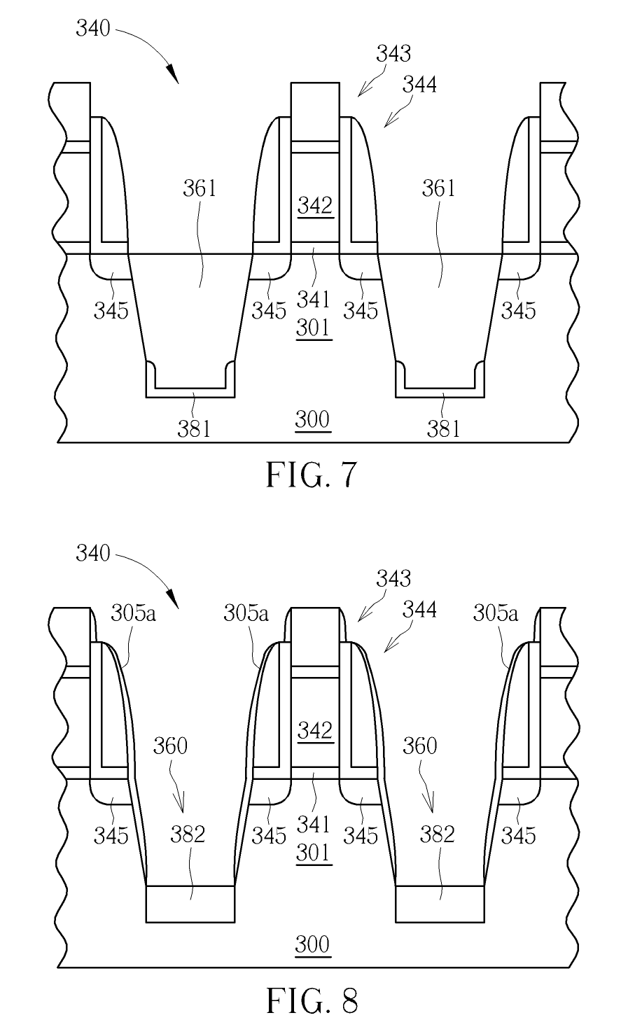

Please refer to FIG. 8, which are schematic diagrams illustrating a method of fabricating a FinFET device according to the second embodiment of the present invention. The formal steps in the present embodiment are similar to those in FIGS. 1-5 in the first embodiment and are not redundantly described herein. As shown in FIG. 8, the differences between the present embodiment and the aforementioned first embodiment are in that the epitaxial layer 382 is formed to fill up the trench 380. After that, the epitaxial structure 361 may also be formed on the epitaxial layer 382 and the detailed formation thereof are all similar to those shown in FIG. 7 in the first embodiment and will not redundantly described herein.

It is noted that the epitaxial layer 382 having a relative greater thickness is formed to fill up the trench, and which may also perform like an anti-type barrier layer in the present embodiment. Thus, the anti-type barrier layer in the present embodiment may obtain preferable current leakproof performance due to the increased thickness thereof. Also, in another embodiment of the present invention, the epitaxial layer may also be formed to not only fill up the trench but also further protrude over the trench (not shown in the drawings), so as to obtain anti-type barrier layer in more preferable current leakproof performance.

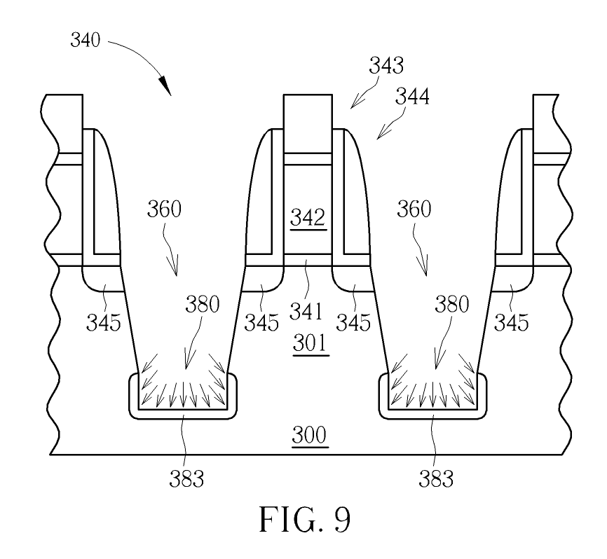

Please refer to FIG. 9, which is a schematic diagram illustrating a method of fabricating a FinFET device according to the third embodiment of the present invention. The formal steps in the present embodiment are similar to those in FIGS. 1-5 in the first embodiment and are not redundantly described herein. As shown in FIG. 9, the differences between the present embodiment and the aforementioned first embodiment are in that an implantation process is performed on the exposed surfaces of the trench 380 to form a doped region 383 thereon to function like the anti-type barrier layer. Specifically, the doped region 383 may include proper dopant according to the conductive type of the transistor required to be formed. For example, if the gate structure 340 is required to form a PMOS transistor in the subsequent processes, the doped region 383 may include an N-type dopant such as VA elements like P, As or Sb. Alternately, if the gate structure 340 is required to form a NMOS transistor in the subsequent processes, the doped region 383 may include a P-type dopant such as IIIA elements like B or In. Following these, an epitaxial structure (not shown in the drawings) may be formed in the trench 380 and the trench 360 to fill up the trenches 360, 380 as shown in FIG. 7 of the first preferred embodiment, or to not fill up the trenches 360, 380, or to further extend over the trenches 360, 380 or top surfaces of the fin shaped structure 301, thereby providing required compressive stress or tensile stress to the channel of the gate structure 340.

It is noted that the doped region 383 in the present embodiment may also perform like the anti-type barrier layer to prevent from current leakage through an interface between the substrate (silicon) and the source/drain regions (the epitaxial structure). Also, the method of the present embodiment is not limited to those steps mentioned above and may further include other forming processes. For example, in another embodiment, an epitaxial layer may also be formed before the epitaxial structure is formed to at least cover the surfaces of the trench 380. In this way, the dopant in the doped region 383 may diffuse into the epitaxial layer while the epitaxial layer is formed, thereby obtaining an anti-type barrier layer extending from substrate 300 to the epitaxial layer (not shown in the drawings) to achieve better improvement on being current leakproof.

In summary, the method of the present invention is mainly characterized by forming an anti-type barrier layer at the interface between the substrate (silicon) and the source/drain regions (the epitaxial structure) of the gate structure for preventing from current leakage issue. The anti-type barrier layer may include an epitaxial layer either disposed on surfaces of the trench or filled in the trench, or a doped region formed on the surfaces of the trench, in which the epitaxial layer and the doped region have a complementary conductive type relative to that of the gate structure. For example, if a PMOS transistor is provided, the epitaxial layer or the doped region may include an N-type dopant such as VA elements like P, As or Sb. Alternately, if a NMOS transistor is provided, the epitaxial layer or the doped region may include a P-type dopant such as IIIA elements like B or In.

Those skilled in the art will readily observe that numerous modifications and alterations of the device and method may be made while retaining the teachings of the invention. Accordingly, the above disclosure should be construed as limited only by the metes and bounds of the appended claims.

1. A method of fabricating a FinFET device, comprising:
forming a fin shaped structure on a substrate;
removing a portion of the fin shaped structure to form a first trench in the fin shaped structure;
forming a cover film partially covering surfaces of the first trench, to expose a portion of the fin shaped structure;
further removing the exposed portion of the fin shaped structure to form a second trench under the first trench; and
forming a barrier layer on surfaces of the second trench.

2. The method of fabricating a FinFET device according to claim 1, wherein the barrier layer is formed through an epitaxial growing process.

3. The method of fabricating a FinFET device according to claim 1, wherein the barrier layer is filled up the second trench.

4. The method of fabricating a FinFET device according to claim 1, wherein the barrier layer is extended over the second trench.

5. The method of fabricating a FinFET device according to claim 1, wherein the barrier layer is formed through an implantation process.

6. The method of fabricating a FinFET device according to claim 1, further comprising:
forming an epitaxial structure filled in the first trench.

7. The method of fabricating a FinFET device according to claim 6, wherein the epitaxial structure is extended over top surfaces of the fin shaped structure.

8. The method of fabricating a FinFET device according to claim 6, further comprising:
in situ doping a dopant while the epitaxial structure is formed.

9. The method of fabricating a FinFET device according to claim 6, further comprising:
implanting a dopant after the epitaxial structure is formed.

10. The method of fabricating a FinFET device according to claim 6, wherein the epitaxial structure comprises a first conductive type.

11. The method of fabricating a FinFET device according to claim 10, wherein the barrier layer comprises a second conductive type and the second conductive type is complementary to the first conductive type.

12. The method of fabricating a FinFET device according to claim 1, wherein the cover film comprises oxide.

13. The method of fabricating a FinFET device according to claim 1, wherein the forming of the cover film comprises:
forming a material layer on the substrate to completely cover the surfaces of the first trench; and
removing a portion of the material layer to form the cover film exposing the portion of the fin shaped structure.

14. The method of fabricating a FinFET device according to claim 1, further comprising:
forming a gate structure across the fin shaped structure.

15. The method of fabricating a FinFET device according to claim 14, wherein the gate structure comprises:
a gate electrode; and
a capping layer formed on the gate electrode, wherein the cover film partially covers the gate structure to expose a portion of the capping layer.

16. The method of fabricating a FinFET device according to claim 1, wherein the second trench is formed completely within the first trench in a projection direction.
